(19) United States
(12) Patent Application Publication
(10) Pub. No.: US 2015/0323302 A1
(43) Pub. Date: Nov. 12, 2015

(54) Flexible Strain Sensor, Method for Producing Same, and Measuring Device Including Same

(71) Applicant: National Sun Yat-Sen University, Kaohsiung City (TW)

(72) Inventors: Wan-Chun Chuang, Kaohsiung City (TW); Wei-Long Chen, Kaohsiung City (TW); Hwai-Ting Lin, Kaohsiung City (TW)

(21) Appl. No.: 14/557,542

(22) Filed: Dec. 2, 2014

(30) Foreign Application Priority Data
May 6, 2014 (TW) 103116136

(51) Int. Cl. G01B 7/16; C23C 14/34

(52) U.S. Cl. CPC G01B 7/16; C23C 14/34

(57) ABSTRACT

A flexible strain sensor includes a substrate layer made of a flexible substrate and a conductive layer coated on the substrate layer. The conductive layer is made of ductile conductive metal material. An electrode is electrically connected to each of two sides of the conductive layer. A measuring device includes the flexible strain sensor, a measuring unit electrically connected to the electrodes of the flexible strain sensor by a signal line, and a processing unit coupled to the measuring unit. A method for producing a flexible strain sensor includes preparing a flexible substrate having a substrate layer. A conductive layer is formed on the flexible substrate by sputtering using silver, wolfram, or aluminum as a target material. An electrode of conductive material is formed on each of the two sides of the conductive layer. The electrodes are electrically connected to the two sides of the conductive layer respectively.

### BACKGROUND OF THE INVENTION

1. Field of the Invention

The present invention relates to a flexible strain sensor and, more particularly, to a flexible strain sensor for measuring elongation of skin, a method for producing the flexible strain sensor, and a measuring device including the flexible strain sensor.

2. Description of the Related Art

Due to high development of medicine and dissemination and popularization of massive medical information assisted by the internet, modern people gradually become concerned in body health and health care. In view of this trend, the future market of products related to muscle training is huge. Thus, people engaged in sport science, development of fitness products, or nutrient manufacturers invest huge resources trying to capture the market of the industry related to muscle training.

Since the muscle training movement requires standards and exactness to effectively achieve the muscle training effect while avoiding injury, the key technique competed by the educational circles and the people engaged in the industry is how to detect whether the target muscle groups are really activated during the body movement to thereby assess the training effect and to thereby serve as a basis for adjustment of the body movement. It is known that activated muscles will compress the skin to elongate the epidermis. Thus, the activation degree of the epidermal muscles can indirectly be detected by measuring the elongation of the human epidermis.

Under the strain effect of the human epidermis, the sensor used on the skin must be flexible to assure reliable fixing for the purpose of avoiding loosening during the body movement. FIG. 1 shows a conventional flexible strain sensor 9 including a soft substrate 91, a plurality of temperature sensors 92, and a plurality of pressure sensors 93. The soft substrate 91 can be a soft printed circuit board. The temperature sensors 92 are mounted on an inner face 91a of the soft substrate 91, and the pressure sensors 93 are mounted on an outer face 91b of the soft substrate 91. The outer face 91b is the face that the soft substrate 91 contacts with the outside, whereas the inner face 91a is the other side of the soft substrate 91.

FIG. 2 shows the structure of one of the pressure sensors 93 of the flexible strain sensor 9. The pressure sensor 93 includes a pair of electrodes 931 and 932. The electrodes 931 and 932 are inter-digital electrodes. The pressure sensor 93 can detect the pressure of the soft substrate 91 in the direction of the normal line. However, even though the conventional flexible sensor 9 is adhered to the human epidermis, since elongated human epidermis can only exert pressure on the soft substrate 91 in the direction of the normal line, the pressure sensor 93 cannot effectively detect the elongation of the human epidermis. In fact, the conventional flexible strain sensor 9 is used on production and design of robots flexible strain sensor and uses the temperature sensors 92 and the pressure sensors 93 to detect the pressure and the temperature. Obviously, the conventional flexible strain sensor 9 is not suitable for measurement of the elongation of the human epidermis.

Production of other flexible strain sensors includes using capacitive detection principle or piezoelectric detection principle, wherein a conductive capacitive layer or a piezoelectric material is bonded to a flexible substrate to form a flexible strain sensor. However, the flexible strain sensor so produced is similar to the conventional flexible strain sensor 9. Both flexible strain sensors detect the normal pressure exerted on the flexible substrate such that they cannot effectively detect the elongation of the human epidermis when they are adhered to the human epidermis. Namely, these flexible strain sensors cannot measure the elongation of the human epidermis while the skin is compressed by the activated muscles.

Thus, a need exists for an improved flexible strain sensor for measuring the elongation of the human epidermis and, hence, detecting the activation degree of the epidermal muscles, which can assist in finding the incorrect movement during the training course and in reminding the trainee to adjust his body to the exact position, thereby increasing the muscle training effect and reducing the injury risks and thereby greatly expanding the development space of the industry related to muscle training.

### SUMMARY OF THE INVENTION

An objective of the present invention is to provide a flexible strain sensor that is stretched to change the resistance of a conductive layer thereof when the human epidermis elongates, achieving measurement of the elongation of the human epidermis.

Another objective of the present invention is to provide a measuring device including the flexible strain sensor, wherein the measuring device includes a measuring unit to measure the resistance of the conductive layer and to transmit the measurement result to a processing unit. The processing unit calculates the change of the resistance in the conductive layer based on the measurement result, effectively measuring the elongation of the human epidermis to detect whether the epidermal muscles have been activated.

A further objective of the present invention is to provide a method for producing a flexible strain sensor, wherein the conductive layer is formed on a flexible substrate by sputtering. The production procedures are simple, the technical demand is low, and the production time is short. Thus, the production costs of the flexible strain sensor are reduced.

The present invention fulfills the above objectives by providing, in an aspect, a flexible strain sensor including a substrate layer made of a flexible substrate and a conductive layer coated on the substrate layer. The conductive layer is made of ductile conductive metal material. An electrode is electrically connected to each of two sides of the conductive layer.

The conductive layer can be made of silver, wolfram, or aluminum.

The flexible strain sensor can further include an interlayer located between the substrate layer and the conductive layer and made of titanium, aluminum, or chromium.

The substrate layer can be made of artificial skin.

The artificial skin can be comprised of a semipermeable membrane and a colloid. The colloid is applied to a face of the substrate layer opposite to the conductive layer.

In a second aspect, a measuring device includes a flexible strain sensor, a measuring unit, and a processing unit. The flexible strain sensor includes a substrate layer made of a flexible substrate and a conductive layer coated on the substrate layer. The conductive layer is made of ductile conductive metal material. An electrode is electrically connected to each of two sides of the conductive layer. The measuring unit is electrically connected to the two electrodes of the flexible strain sensor by a signal line. The processing unit is coupled to the measuring unit.

The measuring unit can be a resistance measuring apparatus, such as a resistance meter, a galvanometer, or a data logger.

The processing unit can be a computing device, such as a computer host, an embedded system, or a microcontroller unit.

In a third aspect, a method for producing a flexible strain sensor includes preparing a flexible substrate including a substrate layer; using silver, wolfram, or aluminum as a target material and forming a conductive layer on the flexible substrate by sputtering; and forming an electrode of conductive material on each of two sides of the conductive layer, with the electrodes electrically connected to the two sides of the conductive layer respectively.

Sputtering of the conductive layer using silver, wolfram, or aluminum as the target material can be carried out with a power of 30-60 W for 10-90 minutes at a processing pressure of 1.8×10⁻²-7.8×10⁻² torr and at an ambient temperature of 20-44° C.

Preparing the flexible substrate can include preparing the flexible substrate having an interlayer, wherein the interlayer is disposed on the substrate layer by supporting and by using titanium, aluminum, or chromium as a target material, and wherein the conductive layer is disposed on the interlayer.

Sputtering of the interlayer using titanium, aluminum, or chromium as the target material can be carried out with a power of 30-60 W for 10-90 minutes at a processing pressure of 1.8×10⁻²-7.8×10⁻² torr and at an ambient temperature of 20-44° C.

The substrate layer used in the method for producing a flexible strain sensor can be made of artificial skin.

The present invention will become clearer in light of the following detailed description of illustrative embodiments of this invention described in connection with the drawings.

### BRIEF DESCRIPTION OF THE DRAWINGS

FIG. 1 is a perspective view of a conventional flexible strain sensor.

FIG. 2 is a diagrammatic view of a pressure sensor of the conventional flexible strain sensor.

FIG. 3 is a cross sectional view of a flexible strain sensor of a first embodiment according to the present invention.

FIG. 4 is a cross sectional view of a flexible strain sensor of a second embodiment according to the present invention.

FIG. 5 is a diagrammatic view of a measuring device including the flexible strain sensor according to the present invention.

FIG. 6 is a diagram illustrating a change of resistance of a conductive layer of the flexible strain sensor during use of a measuring device including the flexible strain sensor.

FIG. 7 is a block diagram illustrating an example of a method for producing the flexible strain sensor according to the present invention.

FIG. 8a is a cross sectional view illustrating a substrate preparation step of the example of the method for producing the flexible strain sensor according to the present invention.

FIG. 8b is a cross sectional view illustrating another step of the example of the method for producing the flexible strain sensor according to the present invention, wherein an interlayer is formed on the substrate.

FIG. 8c is a cross sectional view illustrating a further step of the example of the method for producing the flexible strain sensor according to the present invention, wherein a conductive layer is formed on the interlayer.

FIG. 8d is a cross sectional view illustrating still another step of the example of the method for producing the flexible strain sensor according to the present invention, wherein two electrodes are formed on two sides of the conductive layer.

FIG. 9 is a top view of a flexible strain sensor produced by the example of the method according to the present invention.

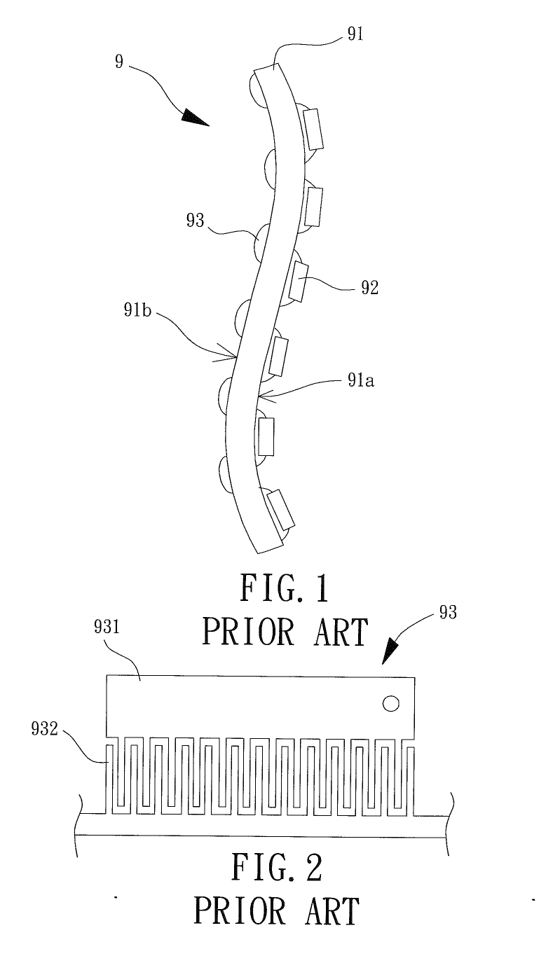

### DETAILED DESCRIPTION OF THE INVENTION

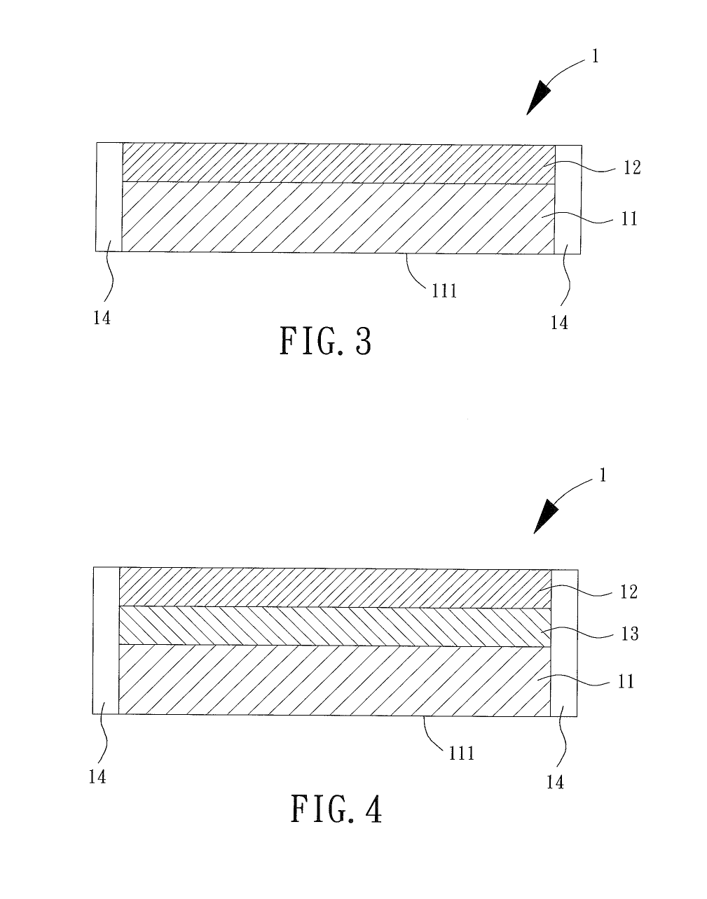

FIG. 3 is a cross sectional view of a flexible strain sensor of a first embodiment according to the present invention. The flexible strain sensor 1 includes a substrate layer 11 and a conductive layer 12. The conductive layer 12 covers the substrate layer 11. Each of two sides of the conductive layer 12 is electrically connected to an electrode 14. Preferably, the two electrodes 14 are respectively bonded to the substrate layer 11.

Specifically, the substrate layer 11 is made of a flexible substrate. In this embodiment, the substrate layer 11 is preferably made of artificial skin. More specifically, the artificial skin is comprised of a semipermeable membrane (such as polyurethane semipermeable membrane) and a colloid (such as a hydrophilic colloid). The colloid is preferably applied to a face 111 of the substrate layer 11 opposite to the conductive layer 12. The face 111 of the substrate layer 11 can be adhered by the colloid to the human epidermis or any location to which the flexible strain sensor 1 is to be applied.

The conductive layer 12 is coated on the substrate layer 11 by sputtering. Thus, the conductive layer 12 can be made of metal material with good ductility and good conductivity, such as gold, silver, copper, aluminum, or wolfram. Nevertheless, in this embodiment, the conductive layer 12 is preferably made of silver, wolfram, or aluminum due to restriction by the processing needs. The electrodes 14 can be made of any conductive material. The present invention is not limited in this regard.

In practical use of the flexible strain sensor 1 of the first embodiment, the conductive layer 12 could peel or even fall from the substrate layer 11 due to extensive elongation of the substrate layer 11 or long-term use. Namely, the structural strength and durability of the flexible strain sensor 1 of the first embodiment could be further improved. In view of this need, FIG. 4 shows a cross sectional view of a flexible strain sensor 1 of a second embodiment according to the present invention. The second embodiment is different from the first embodiment by that an interlayer 13 is provided between the substrate layer 11 and the conductive layer 12. The interlayer 13 is preferably made of titanium, aluminum, or chromium.

Specifically, the interlayer 13 is disposed on the substrate layer 11 by sputtering, and the conductive layer 12 is disposed on the interlayer 13 by sputtering. By this arrangement, the interlayer 13 can effectively increase the adherence of the conductive layer 12 on the substrate layer 11, avoiding the conductive layer 12 from peeling or falling from the substrate layer 11.

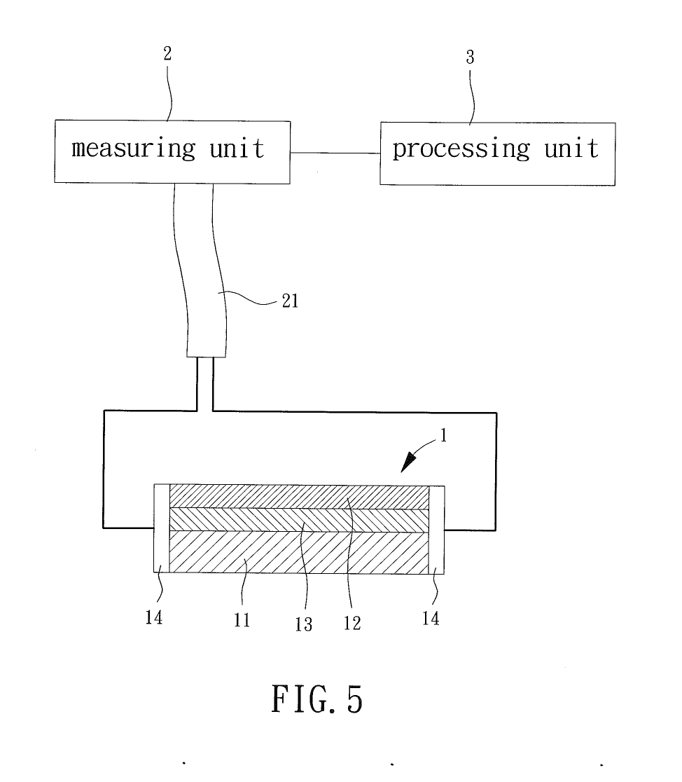

With reference to FIG. 5, in practical use of the flexible strain sensor 1 of the first embodiment and the second embodiment, the flexible strain sensor 1, a measuring unit 2, and a processing unit 3 can be assembled to form a measuring device. The measuring unit 2 is electrically connected to the two electrodes 14 of the flexible strain sensor 1. The processing unit 3 is coupled to the measuring unit 2.

The measuring unit 2 includes a resistance measuring apparatus capable of measuring the resistance of the flexible strain sensor 1, such as a resistance meter, a galvanometer, or a data logger. As a non-restrictive example, the measuring unit 2 is an E34970A type data logger manufactured by Agilent Technologies. The measuring unit 2 is electrically connected to the two electrodes 14 of the flexible strain sensor 1 by a signal line 21. The signal line 21 can be a coaxial cable or any other signal transmission line.

The processing unit 3 can be a computing device, such as a computer host, an embedded system, or a microcontroller unit (MCU). The processing unit 3 can be coupled to the measuring unit 2 by wire connection (such as Ethernet), wireless connection (such as a wireless network), or a combination thereof (such as a heterogeneous network) to permit data transmission between the processing unit 3 and the measuring unit 2.

By providing the above measuring device, when the face 111 of the substrate layer 11 opposite to the conductive layer 12 is adhered and fixed to the human epidermis, if the epidermis elongates due to compression of the skin by activated muscles during body movement, the substrate layer 11 will be stretched under the elongation of the epidermis, such that the substrate layer 11 deforms and generates strain. Since the conductive layer 12 is made of metal material with good ductility and good conductivity and covers the substrate layer 11, the conductive layer 12 deforms together with the substrate layer 11 and generates the same strain. The strain affects the resistance of the conductive layer 12 between the two electrodes 14. Namely, the measuring unit 2 can measure the resistance of the conductive layer 12 between the two electrodes 14 through the signal line 21, and the measurement result is transmitted to the processing unit 3 and is used as a basis for judging the strain of the substrate layer 11 and the conductive layer 12. The strain is directly proportional to the resistance of the conductive layer 12. The principal related to the strain and the resistance of the conductive layer 12 can be appreciated by one having ordinary skill in the art. Redundant description is not required.

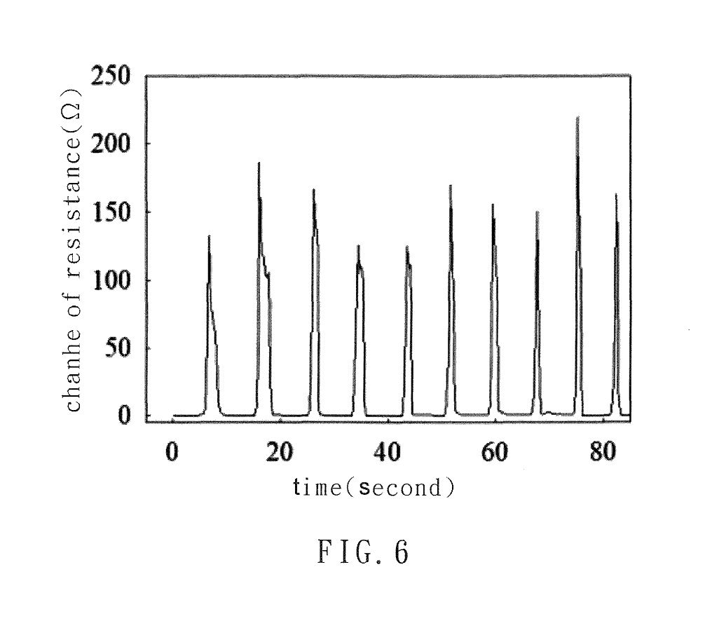

As an example, when a user uses a Roman chair to proceed with stiff-legged deadlift training, the substrate layer 11 is adhered and fixed to the epidermis adjacent to the erector spinae muscles of the lower back of the user. The measuring unit 2 measures the resistance of the conductive layer 12 between the two electrodes 14 through the signal line 21, and the measurement result is transmitted to the processing unit 3. The processing unit 3 calculates the change of the resistance of the conductive layer 12 based on the measurement result. As can be seen from FIG. 6, the change of the resistance of the conductive layer 12 is 159.47±21.43Ω, which is the change of the resistance corresponding to 32% elongation of the substrate layer 11 and the conductive layer 12. Thus, the measuring device can effectively measure the elongation of the human epidermis by the flexible strain sensor 1 to thereby detect whether the epidermal muscles have been activated. In a case that the user again proceeds with stiff-legged deadlift training and again uses the measurement device to proceed with measurement, if the change of the resistance calculated by the processing unit 3 is smaller than 159.47Ω by a certain percentage, this means the elongation of the epidermis adjacent to the erector spinae muscles of the lower back of the user is too small. This could be the result of incorrect movement, and the erector spinae muscles of the lower back of the user are not properly activated. Thus, the user has to adjust the gesture to assure the muscle training effect. On the other hand, if the change of the resistance calculated by the processing unit 3 is larger than 159.47Ω by a certain percentage, this means the elongation of the epidermis adjacent to the erector spinae muscles of the lower back of the user is too large. This could be the result of vigorous movement, and the erector spinae muscles of the lower back of the user could be injured. Thus, the user has to adjust the gesture to reduce the injury risks.

In view of the foregoing, the flexible strain sensor 1 of the first and second embodiments according to the present invention can reliably be stretched when the human epidermis is stretched, and the resistance of the conductive layer 12 is changed to reliably achieve the effect of measuring the elongation of the human epidermis.

Furthermore, the measuring device with the flexible strain sensor 1 can detect the resistance of the conductive layer 12 by the measuring unit 2, and the measurement result is transmitted to the processing unit 3. The processing unit 3 can calculate the change of the resistance of the conductive layer 12 based on the measurement result. Since the change of the resistance of the conductive layer 12 is related to the strain of the conductive layer 12, the processing unit 3 can effectively measure the elongation of the human epidermis, reliably achieving the effect of detecting whether the epidermal muscles have been activated.

Note that when the face 111 of the substrate layer 11 opposite to the conductive layer 12 is adhered and fixed to the human epidermis, the connection wires of the two electrodes 14 should be as parallel to the muscle fibers of the target muscle group as possible. Thus, the elongation resulting from compression of the human epidermis due to activation of the muscle group can properly stretch the substrate layer 11, assuring that the elongation of the human epidermis can effectively be measured by the flexible strain sensor 1, which can be appreciated by one having ordinary skill in the art.

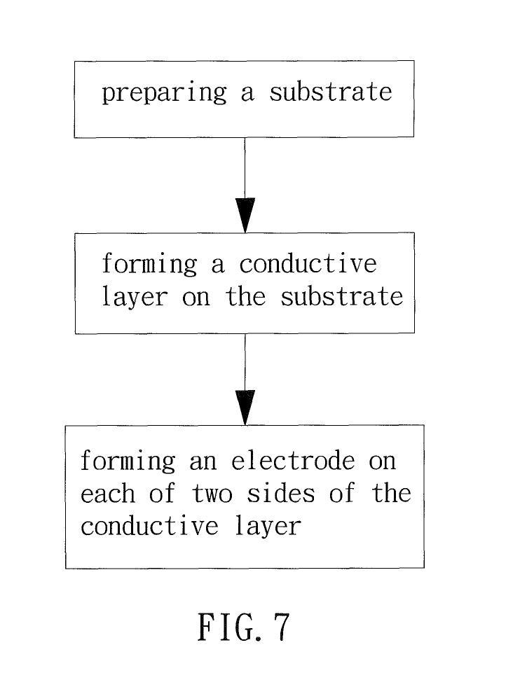

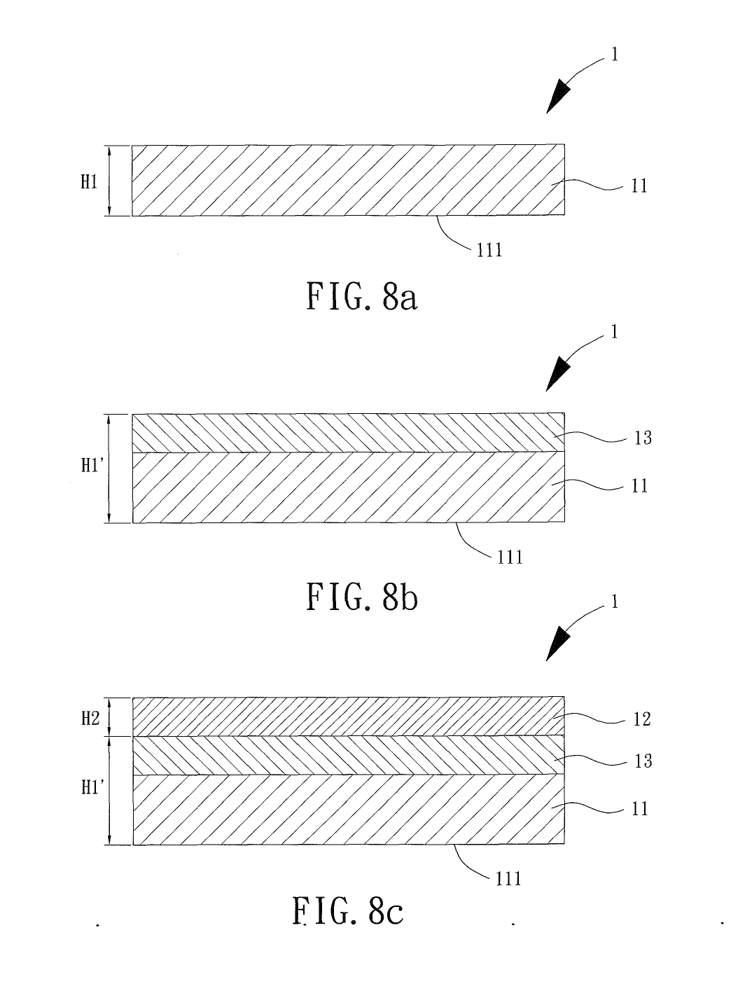

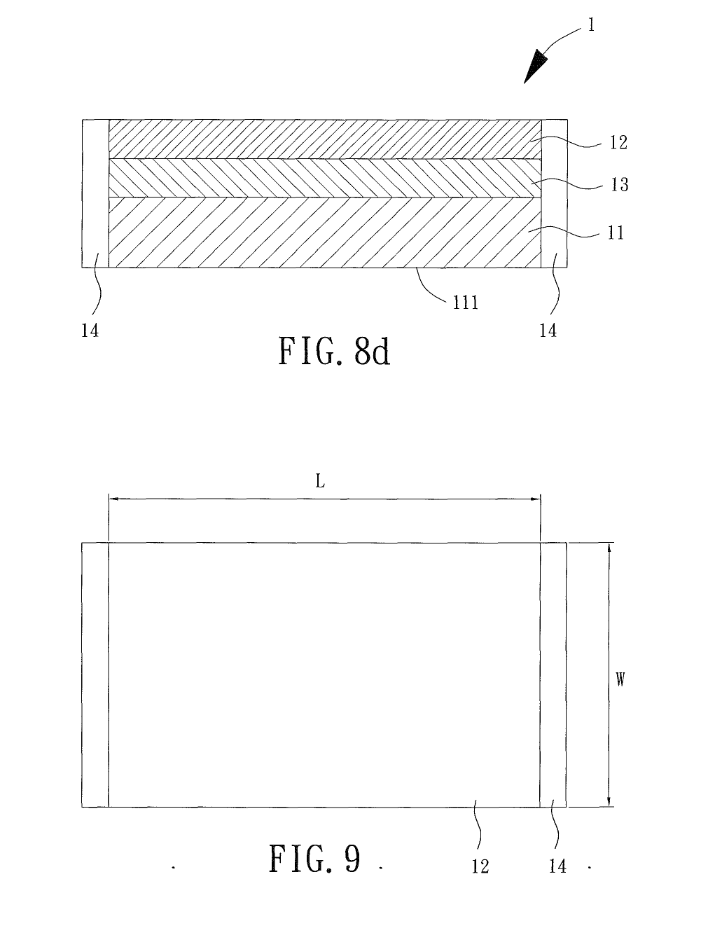

FIG. 7 is a block diagram illustrating an example of a method for producing the flexible strain sensor according to the present invention. The method can be used to produce the flexible strain sensor 1 of the first embodiment or the second embodiment. Firstly, a flexible substrate is prepared and includes a substrate layer 11. The substrate layer 11 can be made of artificial skin. As can be seen from FIG. 8a, the substrate layer 11 has a substrate thickness H1. If it is intended to produce the flexible strain sensor 1 of the second embodiment, the flexible substrate further includes an interlayer 13. The interlayer 13 is disposed on the substrate layer 11 by sputtering. The interlayer 13 is preferably made of titanium, aluminum, or chromium. Thus, titanium, aluminum, or chromium is used as the target material during sputtering for forming the interlayer 13. Examples of the operating conditions of sputtering are shown in Table 1. However, the present invention is not limited to these examples.

TABLE 1
Operating Conditions of Sputtering

| operating conditions | range | preferred condition |
|---|---|---|
| power | 30-60 W | 50 W |
| sputtering time | 10~90 min | 30 min |
| processing temperature | 1.8 × 10⁻²-7.8 × 10⁻² torr | 1.8 × 10⁻² torr |
| ambient temperature | 20-44° C. | 28° C. |

As can be seen from FIG. 8b, if the flexible substrate includes the substrate layer 11 and the interlayer 13, the substrate layer 11 and the interlayer 13 together have a substrate thickness H1′. Then, the method for producing the flexible strain sensor 1 includes forming a conductive layer 12 on the flexible substrate. The conductive layer 12 is disposed on the substrate layer 11 or the interlayer 13 by sputtering. Since the conductive layer 12 is preferably made of silver, wolfram, or aluminum, sputtering of the conductive layer 12 is carried out by using silver, wolfram, or aluminum as the target material. The operating conditions of sputtering can be the same as, but not limited to, those shown in Table 1. As can be seen from FIG. 8c, the conductive layer 12 has a conductive thickness H2. In this embodiment, the substrate thickness H1, H1′ of the flexible substrate can be about 35 mm, and the conductive thickness H2 of the conductive layer 12 can be about 0.0016 mm. However, the present invention is not limited to these examples.

After the conductive layer 12 is formed on and covers the substrate, as can be seen from FIG. 8d, an electrode 14 is formed on each of two sides of the conductive layer 12. The two electrodes 14 are made of conductive material and are electrically connected to the two sides of the conductive layer 12 respectively. In production of the two electrodes 14, the two electrodes 14 can be bonded to the substrate layer 11 respectively to increase the bonding strength between the two electrodes 14 and the conductive layer 12.

By the above procedures, the example of the method for producing a flexible strain sensor according to the present invention can accomplish production of the flexible strain sensor 1 of the first embodiment or the second embodiment. As can be seen from FIG. 9, the conductive layer 12 of the flexible strain sensor 1 produced from the example of the method for producing a flexible strain sensor has a length L and a width W respectively about 40-50 mm and 25 mm, such that the size of the flexible strain sensor 1 is suitable to be adhered to the human epidermis.

In the example of the method for producing a flexible strain sensor according to the present invention, the conductive layer 12 can cover the flexible substrate by simply using sputtering. The production procedures are simple, the technical demand is low, and the production time is short. Thus, the production costs of the flexible strain sensor are reduced.

In view of the foregoing, the substrate layer 11 according to the present invention can measure the elongation of the human epidermis. Thus, the measuring device with the flexible strain sensor 1 can effectively detect whether the epidermal muscles have been activated. The incorrect movement during the training course can be found to remind the user of adjusting the gesture to the proper position, increasing the muscle training effect while reducing the injury risks. Furthermore, the method for producing a flexible strain sensor according to the present invention can effectively reduce the product costs of the flexible strain sensor 1 by forming the conductive layer 12 on the flexible substrate by sputtering, thereby greatly expanding the development space of the industry related to muscle training.

Thus since the invention disclosed herein may be embodied in other specific forms without departing from the spirit or general characteristics thereof, some of which forms have been indicated, the embodiments described herein are to be considered in all respects illustrative and not restrictive. The scope of the invention is to be indicated by the appended claims, rather than by the foregoing description, and all changes which come within the meaning and range of equivalency of the claims are intended to be embraced therein.

What is claimed is:

1. A flexible strain sensor comprising:
a substrate layer made of a flexible substrate; and
a conductive layer coated on the substrate layer, with the conductive layer made of ductile conductive metal material, and with an electrode electrically connected to each of two sides of the conductive layer.

2. The flexible strain sensor as claimed in claim 1, wherein the conductive layer is made of silver, wolfram, or aluminum.

3. The flexible strain sensor as claimed in claim 1, further comprising an interlayer between the substrate layer and the conductive layer, with the interlayer made of titanium, aluminum, or chromium.

4. The flexible strain sensor as claimed in claim 1, wherein the substrate layer is made of artificial skin.

5. The flexible strain sensor as claimed in claim 4, wherein the artificial skin is comprised of a semipermeable membrane and a colloid, and wherein the colloid is applied to a face of the substrate layer opposite to the conductive layer.

6. A measuring device comprising:
a flexible strain sensor including:
a substrate layer made of a flexible substrate; and
a conductive layer coated on the substrate layer, with the conductive layer made of ductile conductive metal material, and with an electrode electrically connected to each of two sides of the conductive layer;
a measuring unit electrically connected to the two electrodes of the flexible strain sensor by a signal line; and
a processing unit coupled to the measuring unit.

7. The measuring device as claimed in claim 6, wherein the measuring unit includes a resistance measuring apparatus, such as a resistance meter, a galvanometer, or a data logger.

8. The measuring device as claimed in claim 6, wherein the processing unit is a computing device, such as a computer host, an embedded system, or a microcontroller unit.

9. A method for producing a flexible strain sensor, comprising:
preparing a flexible substrate including a substrate layer;
using silver, wolfram, or aluminum as a target material and forming a conductive layer on the flexible substrate by sputtering; and
forming an electrode of conductive material on each of two sides of the conductive layer, with the electrodes electrically connected to the two sides of the conductive layer respectively.

10. The method for producing a flexible strain sensor as claimed in claim 9, wherein sputtering of the conductive layer using silver, wolfram, or aluminum as the target material is carried out with a power of 30-60 W for 10-90 minutes at a processing pressure of 1.8×10⁻²-7.8×10⁻² torr and at an ambient temperature of 20-44° C.

11. The method for producing a flexible strain sensor as claimed in claim 9, wherein preparing the flexible substrate includes preparing the flexible substrate having an interlayer, wherein the interlayer is disposed on the substrate layer by supporting and by using titanium, aluminum, or chromium as a target material, and wherein the conductive layer is disposed on the interlayer.

12. The method for producing a flexible strain sensor as claimed in claim 11, wherein sputtering of the interlayer using titanium, aluminum, or chromium as the target material is carried out with a power of 30-60 W for 10-90 minutes at a processing pressure of 1.8×10⁻²-7.8×10⁻² torr and at an ambient temperature of 20-44° C.

13. The method for producing a flexible strain sensor as claimed in claim 9, wherein the substrate layer is made of artificial skin.
